(19) United States
(12) Patent Application Publication
(10) Pub. No.: US 2025/0224676 A1
(43) Pub. Date: Jul. 10, 2025

(54) FILM FORMING METHOD AND FILM FORMING APPARATUS

(71) Applicant: Tokyo Electron Limited, Tokyo (JP)

(72) Inventors: Kazuki YAMADA, Nirasaki City (JP); Hiroki MURAKAMI, Nirasaki City (JP); Shuichiro SAKAI, Nirasaki City (JP); Tomohito YAMAJI, Nirasaki City (JP)

(21) Appl. No.: 19/089,356

(22) Filed: Mar. 25, 2025

Related U.S. Application Data
(63) Continuation of application No. PCT/JP2023/033327, filed on Sep. 13, 2023.

(30) Foreign Application Priority Data
Sep. 27, 2022 (JP) 2022-153618

(51) Int. Cl. G03F 7/09; G03F 7/11; G03F 7/34

(52) U.S. Cl. CPC G03F 7/094; G03F 7/11; G03F 7/343

(57) ABSTRACT

A film forming method includes: preparing a substrate including a resist film with an opening formed on a top surface; infiltrating a metal into at least an upper portion of the resist film by supplying a metal-containing gas containing the metal to the substrate; and selectively forming a protective film containing silicon and oxygen on the top surface of the resist film compared to a side surface and a bottom surface of the opening by supplying a precursor gas containing silanol to the substrate.

### CROSS-REFERENCE TO RELATED APPLICATION

This application is a bypass continuation application of International Patent Application No. PCT/JP2023/033327 having an international filing date of Sep. 13, 2023 and designating the United States, the international application being based upon and claiming the benefit of priority from Japanese Patent Application No. 2022-153618, filed on Sep. 27, 2022, the entire contents of which are incorporated herein by reference.

### TECHNICAL FIELD

The present disclosure relates to a film forming method and a film forming apparatus.

### BACKGROUND

Patent Document 1 discloses a technique for infiltrating a metal into a resist film. Patent Document 2 discloses a technique for forming a thin film of silicon dioxide on a substrate by alternately supplying a metal precursor such as trimethylaluminum (TMA) and silanol such as tris(tert-pentoxy) silanol (TPSOL) to the substrate.

### PRIOR ART DOCUMENTS

### Patent Documents

Patent Document 1: Japanese Patent Laid-Open Publication No. 2020-38929
Patent Document 2: Japanese Patent Laid-Open Publication No. 2010-10686

### SUMMARY

According to one embodiment of the present disclosure, there is provided a film forming method including: preparing a substrate including a resist film with an opening formed on a top surface; infiltrating a metal into at least an upper portion of the resist film by supplying a metal-containing gas containing the metal to the substrate; and selectively forming a protective film containing silicon and oxygen on the top surface of the resist film compared to a side surface and a bottom surface of the opening by supplying a precursor gas containing silanol to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing a film forming method according to an embodiment.

FIG. 2A is a diagram showing an example of S101.

FIG. 2B is a diagram showing an example of S102.

FIG. 2C is a diagram showing an example of S103.

FIG. 3A is a diagram showing a modified example of FIG. 2A.

FIG. 3B is a diagram showing a modified example of FIG. 2B.

FIG. 3C is a diagram showing a modified example of FIG. 2C.

FIG. 4 is a diagram showing an example of an infrared spectroscopic spectrum of a resist film to which only TMA gas is supplied, and an example of an infrared spectroscopic spectrum of a resist film to which TMA gas and TPSOL gas are supplied in this order.

FIG. 5 is a flowchart showing a post-process of a film forming method according to an embodiment.

FIG. 6A is a diagram showing an example of S201.

FIG. 6B is a diagram showing an example of S202.

FIG. 6C is a diagram showing an example of S203.

FIG. 7 is a flowchart showing a film forming method according to a first modified example.

FIG. 8A is a diagram showing an example of S301.

FIG. 8B is a diagram showing an example of S302.

FIG. 8C is a diagram showing an example of S303.

FIG. 8D is a diagram showing an example of S304.

FIG. 8E is a diagram showing an example of S305.

FIG. 8F is a diagram showing an example of S306.

FIG. 9 is a flowchart showing a film forming method according to a second modified example.

FIG. 10A is a diagram showing an example of S401.

FIG. 10B is a diagram showing an example of S402.

FIG. 10C is a diagram showing an example of S403.

FIG. 10D is a diagram showing an example of S404.

FIG. 10E is a diagram showing an example of S405.

FIG. 10F is a diagram showing an example of S406.

FIG. 11 is a cross-sectional view showing a film forming apparatus according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure are described in detail with reference to the accompanying drawings. Like reference numerals are given to like or corresponding configurations throughout the drawings, and a redundant description thereof may be omitted.

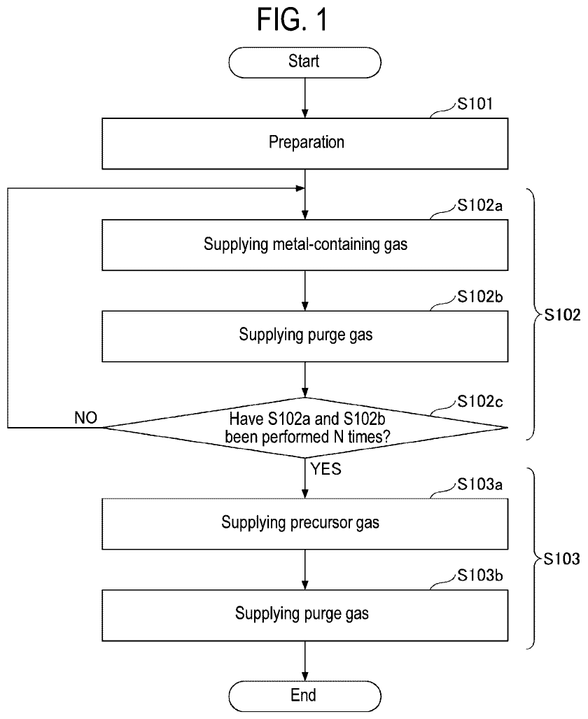

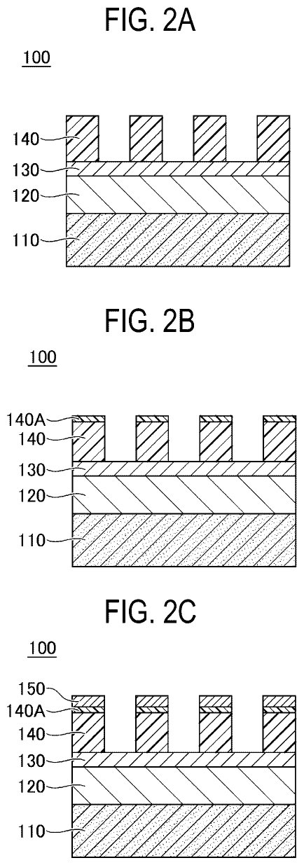

A film forming method according to an embodiment is described with reference to FIGS. 1, 2A to 2C, and 3A to 3C. The film forming method includes, for example, steps S101 to S103 shown in FIG. 1. Step S101 includes preparing a substrate 100 shown in FIG. 2A. Preparing the substrate 100 includes, for example, loading the substrate 100 into an inside of a processing container.

The substrate 100 includes, for example, a base substrate 110, an etching target film 120, a hard mask film 130, and a resist film 140 in this order. The base substrate 110 is, for example, a silicon wafer, a compound semiconductor wafer, or a glass substrate.

The etching target film 120 serves to transfer an opening pattern of the resist film 140. The etching target film 120 is, for example, a spin-on carbon film. The spin-on carbon film is an amorphous film containing carbon (C) as a main component.

The hard mask film 130 is used when the resist film 140 has a thin film thickness. An example of the resist film 140 with a thin film thickness is an extreme ultraviolet (EUV) exposure resist film. The hard mask film 130 is, for example, a spin-on glass film. The spin-on glass film is an amorphous film containing silicon (Si) and oxygen (O) as main components.

The resist film 140 includes an opening formed on a top surface thereof. The resist film 140 is formed from a photoresist composition. The photoresist composition is, for example, chemically amplified. The resist film 140 contains a functional group that introduces a metal in step S102 described later. The functional group may be a typical one, for example, a phenyl group or an acrylic group.

Step S102 includes infiltrating the metal into at least an upper portion of the resist film 140, i.e., causing the metal to enter at least the upper portion of the resist film 140, by supplying a metal-containing gas containing the metal to the substrate 100, as shown in FIG. 2B. In FIG. 2B, reference symbol 140A denotes a portion of the resist film 140 into which the metal has been infiltrated.

The metal enters an inside of the resist film 140 from a surface of the resist film 140 through, for example, a nucleophilic substitution reaction. The metal includes a metal or semimetal having Lewis acid characteristics, or a compound thereof. Specifically, the metal includes one or more elements selected from, for example, Al, Ti, Zr, Zn, Hf, B, and In.

As the metal-containing gas, for example, an organometallic compound gas is used. The metal is more easily infiltrated as a molecular weight of the organometallic compound gas decreases. The organoaluminum compound gas is, for example, trimethylaluminum (TMA) gas or triethylaluminum (TEA) gas. The organotitanium compound gas is, for example, tetrakis(dimethylamino) titanium (TDMAT) gas.

Step S102 includes, for example, supplying the metal-containing gas (step S102a) and supplying a purge gas (step S102b). The purge gas discharges the metal-containing gas remaining at the inside of the processing container to an outside of the processing container. The purge gas also discharges an excess metal-containing gas, which is physically adsorbed onto the surface of the resist film 140, to the outside of the processing container.

Step S102 may include checking whether steps S102a and S102b have been performed N times (where N is an integer equal to or greater than 1) (step S102c). If N is an integer equal to or greater than 2, step S102 performs steps S102a and S102b multiple times. Herein, N may be 1.

In an n-th (where n is an integer equal to or greater than 1) iteration of step S102b, the purge gas discharges the excess metal-containing gas, which is physically adsorbed onto the surface of the resist film 140, to the outside of the processing container. This makes it easier for the metal to be infiltrated into the inside of the resist film 140 from the surface of the resist film 140 in the (n+1)-th iteration of step S102a.

An infiltration depth and an infiltration amount of the metal are mainly controlled by the number of times, N, that steps S102a and S102b are performed, a pressure of the metal-containing gas, and a temperature of the substrate 100. The greater the iteration number N, the greater the pressure of the metal-containing gas, and the higher the temperature of the substrate 100, the easier it is for the metal to be infiltrated into the resist film 140.

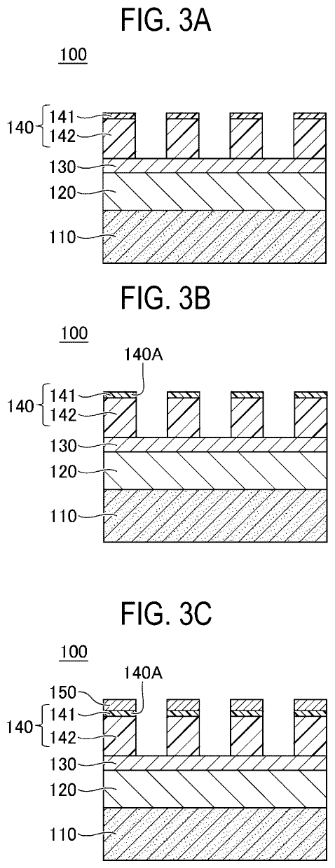

By adjusting the pressure of the metal-containing gas or the temperature of the substrate 100, it is also possible to infiltrate the metal only into the upper portion of the resist film 140, as shown in FIG. 2B. In addition, as shown in FIG. 3A, the resist film 140 may include a multi-layer structure so that the metal may be selectively infiltrated into the upper portion of the resist film 140.

As shown in FIG. 3A, the resist film 140 includes an uppermost layer 141 and one or more (one in FIG. 3A) lower layers 142 provided below the uppermost layer 141. The metal is infiltrated into the uppermost layer 141 more readily compared to all the lower layers 142. As a result, the metal may be selectively infiltrated into the upper portion of the resist film 140 as shown in FIG. 3B.

The uppermost layer 141 has a higher surface density of a functional group to which the metal is introduced compared to all the lower layers 142. The surface density of the functional group is measured by, for example, X-ray photoelectron spectroscopy (XPS). An area into which the metal is infiltrated can be controlled by the surface density of the functional group.

It is desirable that step S102 be performed at a temperature of 200 degrees C. or less and, further, that it does not use plasma, in order to suppress ashing of the resist film 140. An example of processing conditions for steps S102a and S102b is shown below:

### <Step S102a>

Substrate temperature: 20 degrees C. to 250 degrees C.
Flow rate of TMA gas: 10 sccm to 1,000 sccm Supply time of TMA gas: 10 seconds to 300 seconds
Pressure inside the processing container: 10 Pa to 10,000 Pa

### <Step S102b>

Substrate temperature: 20 degrees C. to 250 degrees C.
Flow rate of N₂ gas: 10 sccm to 10,000 sccm
Supply time of N₂ gas: 10 seconds to 300 seconds
Pressure inside the processing container: 10 Pa to 10,000 Pa

Step S103 includes selectively forming a protective film 150 containing silicon (Si) and oxygen (O) on the top surface of the resist film 140 compared to side and bottom surfaces of the opening of the resist film 140 by supplying a precursor gas containing silanol to the substrate 100, as shown in FIG. 2C or 3C. The metal infiltrated into the resist film 140 functions as a catalyst that promotes a reaction for forming the protective film 150.

The protective film 150 grows starting from the metal infiltrated into the resist film 140. By limiting the area into which the metal is infiltrated, the protective film 150 may be selectively formed and a width of the opening of the resist film 140 may be maintained. The protective film 150 is hardly formed on the side and bottom surfaces of the opening of the resist film 140. The bottom surface of the opening of the resist film 140 is a surface of the hard mask film 130.

As the precursor gas, for example, tris(tert-pentoxy) silanol (TPSOL), triethylsilanol, methylbis(tert-pentoxy) silanol, or tris(tert-butoxy) silanol (TBSOL) is used.

Step S103 includes, for example, supplying the precursor gas (step S103a) and supplying the purge gas (step S103b). The purge gas discharges the precursor gas remaining at the inside of the processing container to the outside of the processing container. The purge gas also discharges an excess precursor gas, which is physically adsorbed onto the surface of the resist film 140, to the outside of the processing container.

In step S103, while steps S103a and S103b are performed only once, steps S103a and S103b may be performed multiple times as in step S102. In an n-th (where n is an integer equal to or greater than 1) iteration of step S103b, the purge gas discharges the excess precursor gas, which is physically adsorbed onto the surface of the resist film 140, to the outside of the processing container. This makes it easier for the protective film 150 to grow in the (n+1)-th iteration of step S103a.

It is desirable that step S103 be performed at a temperature of 200 degrees C. or less and, further, that is does not use plasma, in order to suppress ashing of the resist film 140. An example of processing conditions for steps S103a and S103b is shown below:

### <Step S103a>

Substrate temperature: 20 degrees C. to 250 degrees C.
Flow rate of TPSOL gas: 10 sccm to 1,000 sccm
Supply time of TPSOL gas: 10 seconds to 900 seconds
Pressure inside the processing container: 10 Pa to 10,000 Pa

### <Step S103b>

Substrate temperature: 20 degrees C. to 250 degrees C.
Flow rate of N₂ gas: 10 sccm to 10,000 sccm
Supply time of N₂ gas: 10 seconds to 300 seconds
Pressure inside the processing container: 10 Pa to 10,000 Pa

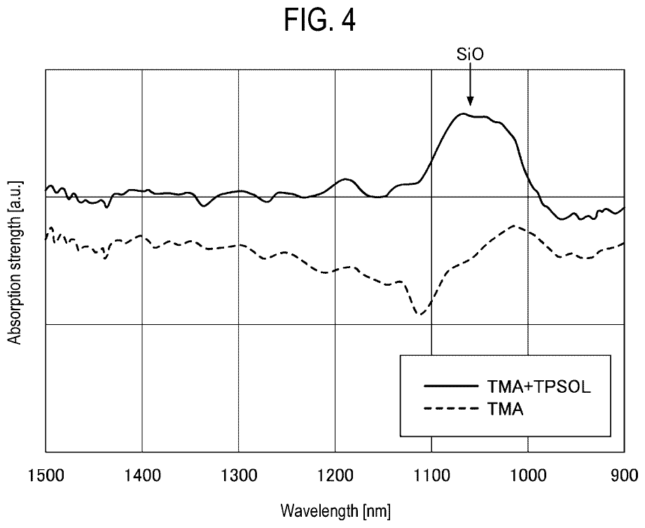

In FIG. 4, a dashed line shows an example of an infrared spectroscopic spectrum of a resist film 140 to which only TMA gas is supplied, and a solid line shows an example of an infrared spectroscopic spectrum of a resist film 140 to which TMA gas and TPSOL gas are supplied in this order. Comparing the solid line and the dashed line, it may be appreciated that it is possible to form a silicon oxide film on the surface of the resist film 140 by supplying TMA gas and TPSOL gas in this order to the surface of the resist film 140.

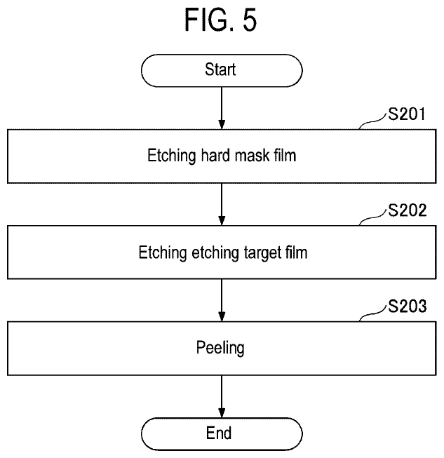

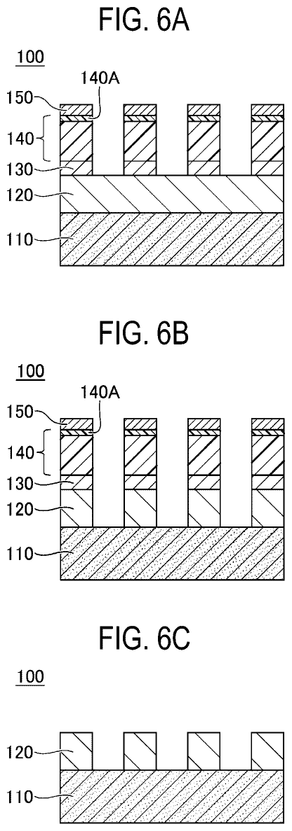

A post-process of the film forming method according to an embodiment is described with reference to FIGS. 5 and 6A to 6C. The post-process includes, for example, steps S201 to S203 shown in FIG. 5. Step S201 includes etching the hard mask film 130 by using the resist film 140 protected by the protective film 150, as shown in FIG. 6A.

The protective film 150 protects the top surface of the resist film 140, so that the resist film 140 may be prevented from being torn even if the film thickness of the resist film 140 is non-uniform. This is particularly effective when the film thickness of the resist film 140 is thin. One example of the resist film 140 with a thin thickness is an EUV exposure resist film.

The protective film 150 is hardly formed on the side and bottom surfaces of the opening of the resist film 140 and is mainly formed on the top surface of the resist film 140. Therefore, an opening pattern having the same line width as that of the resist film 140 may be formed on the hard mask film 130. Also, the hard mask film 130 may not be provided, and step S201 may not be performed.

Step S202 includes etching the etching target film 120 by using the resist film 140 protected by the protective film 150, as shown in FIG. 6B. The protective film 150 protects the top surface of the resist film 140, so that the resist film 140 may be prevented from being torn even if the film thickness of the resist film 140 is non-uniform.

As described above, the protective film 150 is hardly formed on the side and bottom surfaces of the opening of the resist film 140 and is mainly formed on the top surface of the resist film 140. As a result, an opening pattern having the same line width as that of the resist film 140 may be formed on the etching target film 120.

Step S203 includes peeling off the hard mask film 130, the resist film 140, and the protective film 150, as shown in FIG. 6C. For example, step S203 includes removing the resist film 140 and the protective film 150 by etching the hard mask film 130 using dilute hydrofluoric acid (DHF).

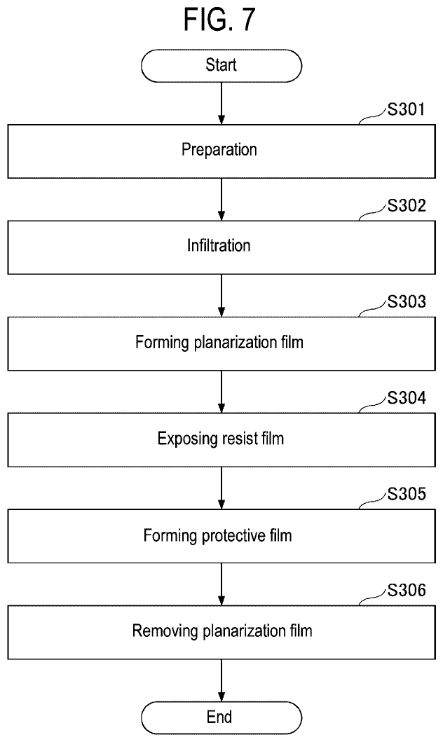

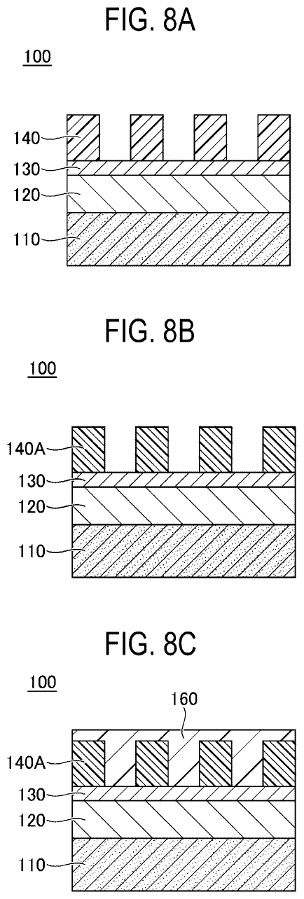

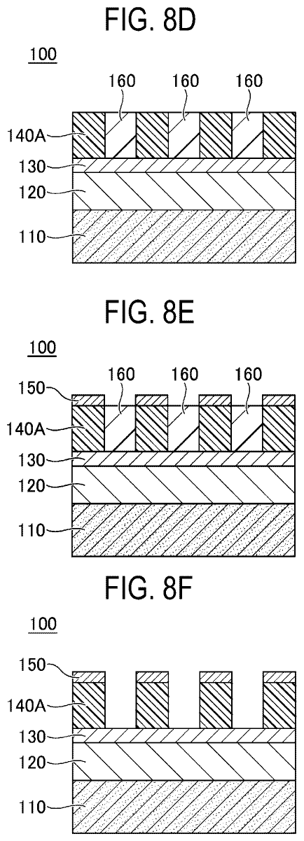

A film forming method according to a first modified example is described with reference to FIGS. 7 and 8A to 8F. The film forming method includes, for example, steps S301 to S306 shown in FIG. 7. Step S301 includes preparing the substrate 100 shown in FIG. 8A. Preparing the substrate 100 includes, for example, loading the substrate 100 into the inside of the processing container.

Step S302 includes, as shown in FIG. 8B, infiltrating the metal into at least the upper portion of the resist film 140 (the entire portion in FIG. 8B) by supplying the metal-containing gas containing the metal to the substrate 100. In FIGS. 8B to 8F, reference symbol 140A is a portion of the resist film 140 into which the metal has been infiltrated.

Step S303 includes forming, on the resist film 140, a planarization film 160 for planarizing a step difference of the resist film 140, as shown in FIG. 8C. The planarization film 160 fills the opening of the resist film 140. The planarization film 160 may be an organic film, like the resist film 140. Herein, unlike the resist film 140, the planarization film 160 is not infiltrated with the metal.

Step S304 includes, as shown in FIG. 8D, exposing the upper portion of the resist film 140 by shaving the planarization film 160 through etching or the like. The planarization film 160 fills the opening of the resist film 140, and the side surface of the opening is covered with the planarization film 160. In FIG. 8D, while a top surface of the planarization film 160 and the top surface of the resist film 140 are disposed on the same plane, the present disclosure is not limited thereto. As long as the side surface of the opening is covered with the planarization film 160, a vicinity of a central portion of the planarization film 160 may be, for example, concave.

Step S305 includes forming the protective film 150 on the upper portion of the resist film 140 as shown in FIG. 8E. The protective film 150 grows starting from the metal that has been infiltrated into the resist film 140. Unlike the resist film 140, the planarization film 160 is not infiltrated with the metal. Therefore, the protective film 150 is selectively formed on the upper portion of the resist film 140 compared to an upper portion of the planarization film 160. Step S305 is performed in the same manner as step S103 in FIG. 1.

Step S306 includes removing the planarization film 160 that blocks the opening of the resist film 140 through etching or the like, as shown in FIG. 8F. Therefore, an underlying layer of the planarization film 160, for example, the hard mask film 130, is exposed in the opening of the resist film 140. If the planarization film 160 is an organic film, a difference in etching rate between the planarization film 160 and the protective film 150 is large, and thus a film thickness of the protective film 150 is hardly reduced.

After step S306, the substrate 100 is subjected to the post-process shown in FIG. 5. The post-process is the same as the above-described embodiment, and therefore a description thereof is omitted.

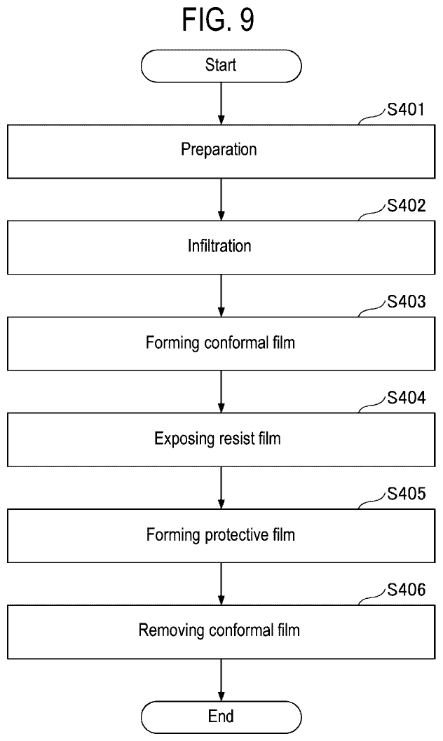

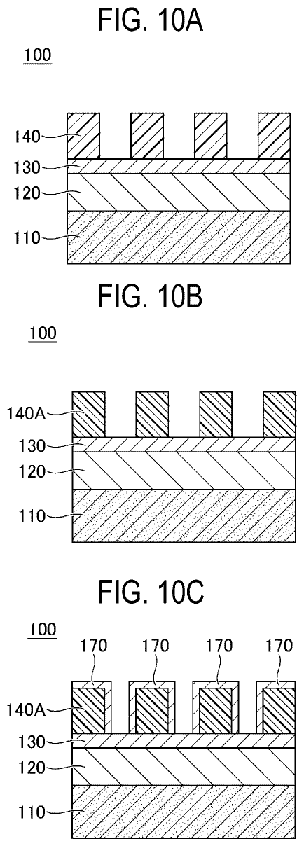

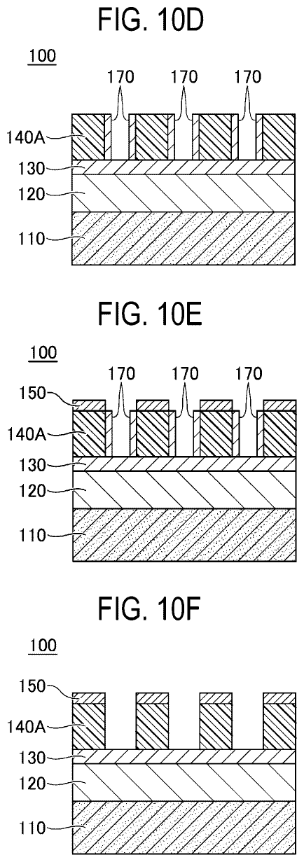

A film forming method according to a second modified example is described with reference to FIGS. 9 and 10A to 10F. The film forming method includes, for example, steps S401 to S406 shown in FIG. 9. Step S401 includes preparing the substrate 100 shown in FIG. 10A. Preparing the substrate 100 includes, for example, loading the substrate 100 into the inside of the processing container.

Step S402 includes, as shown in FIG. 10B, infiltrating the metal into at least the upper portion of the resist film 140 (the entire portion in FIG. 10B) by supplying the metal-containing gas containing the metal to the substrate 100. In FIGS. 10B to 10F, reference symbol 140A denotes a portion of the resist film 140 into which the metal has been infiltrated.

Step S403 includes forming a conformal film 170 along a step difference of the resist film on the top surface of the resist film 140 and on the side surface of the opening of the resist film 140, as shown in FIG. 10C. The conformal film 170 is not formed on the bottom surface of the opening of the resist film 140 but may be formed thereon. The conformal film 170 is, for example, an inorganic film.

The conformal film 170 may be formed in the same manner as the protective film 150. That is, the conformal film 170 may be formed using the precursor gas containing silanol. In this case, the conformal film 170 is formed on the top surface of the resist film 140 and the side surface of the opening, and is hardly formed on the bottom surface of the opening.

Step S404 includes, as shown in FIG. 10D, exposing the upper portion of the resist film 140 by selectively etching an upper portion of the conformal film 170 through anisotropic etching or the like. After step S404, the side surface of the opening of the resist film 140 remains covered with the conformal film 170.

When the conformal film 170 is formed on the bottom surface of the opening of the resist film 140 in step S403, step S404 may include removing the conformal film 170 formed on the bottom surface of the opening of the resist film 140.

Step S405 includes forming the protective film 150 on the upper portion of the resist film 140 as shown in FIG. 10E. The protective film 150 grows starting from the metal that has been infiltrated into the resist film 140. Unlike the resist film 140, the conformal film 170 is not infiltrated with the metal. Therefore, the protective film 150 is selectively formed on the upper portion of the resist film 140. Step S405 is performed in the same manner as step S103 in FIG. 1.

Step S406 includes removing the conformal film 170 remaining on the side surface of the opening of the resist film 140 through etching or the like, as shown in FIG. 10F. In this case, the conformal film 170 and the protective film 150 may be simultaneously etched. If a film thickness of the conformal film 170 is thinner than the film thickness of the protective film 150, the protective film 150 may be left on the upper portion of the resist film 140.

After step S406, the substrate 100 is subjected to the post-process shown in FIG. 5. The post-process is the same as the above-described embodiment, and therefore a description thereof is omitted.

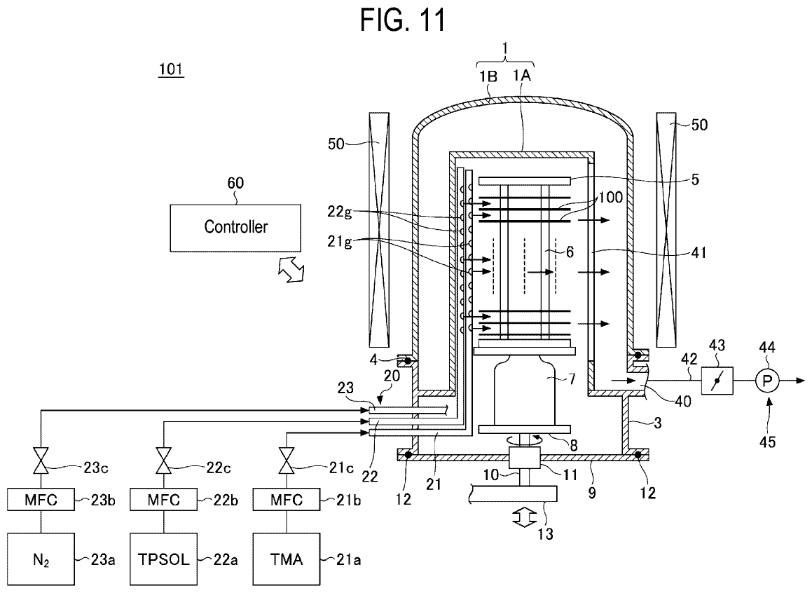

Next, a film forming apparatus 101 for performing at least a part of the film forming method of FIG. 1, 7, or 9 is described with reference to FIG. 11. The film forming apparatus 101 shown in FIG. 11 is an example of a batch type apparatus that simultaneously processes a plurality of substrates 100 arranged in a vertical direction but may be a single-wafer type apparatus that processes the substrates 100 one by one. Hereinafter, a batch type film forming apparatus is described.

The film forming apparatus 101 includes a processing container 1. The processing container 1 includes a roofed cylindrical inner tube 1A with a lower end opened and a roofed cylindrical outer tube 1B that has a lower end opened and covers an outside of the inner tube 1A. The inner tube 1A and the outer tube 1B are made of a heat-resistant material such as quartz and are disposed coaxially to form a double-tube structure. A metal-made manifold 3 molded in a cylindrical shape is connected to an opening at a lower end of the processing container 1 via a seal member 4 such as an O-ring or the like.

The manifold 3 supports the lower end of the processing container 1, and a wafer boat 5 in which substrates 100 are placed in multiple stages is inserted into the processing container 1 from below the manifold 3. In this way, the plurality of substrates 100 is accommodated substantially horizontally in the processing container 1 at intervals in a vertical direction. The wafer boat 5 is made of, for example, quartz. The wafer boat 5 includes three rods 6 (of which two are shown in FIG. 11), and the plurality of substrates 100 are supported by grooves (not shown) formed on the rods 6. The wafer boat 5 is an example of a substrate holder.

The wafer boat 5 is placed on a table 8 via a heat-insulating cylinder 7 made of quartz. The table 8 is supported on a rotary shaft 10 that penetrates a metal-made (stainless steel) lid 9 that opens and closes an opening at a lower end of the manifold 3.

A magnetic fluid seal 11 is provided at a penetrating portion of the rotary shaft 10 so as to airtightly seal and rotatably support the rotary shaft 10. A seal member 12 for keeping the inside of the processing container 1 in a sealed state is provided between a peripheral portion of the lid 9 and the lower end of the manifold 3.

The rotary shaft 10 is attached to a tip of an arm 13 supported by, for example, an elevating mechanism (not shown) such as a boat elevator or the like, and the wafer boat 5 and the lid 9 are raised and lowered together and inserted into and removed from the inside of the processing container 1. The table 8 may be fixedly provided at a side of the lid 9 so that the substrates 100 may be processed without rotating the wafer boat 5.

The film forming apparatus 101 includes a gas supplier 20. The gas supplier 20 supplies a gas to the inside of the processing container 1 (specifically, the inner tube 1A). The gas supplier 20 includes gas supply pipes 21, 22, and 23. The gas supply pipes 21 and 22 are made of, for example, quartz. The gas supply pipes 21 and 22 pass through a sidewall of the manifold 3 inward, are bent upward, and extend vertically. A plurality of gas holes 21g and 22g is formed at predetermined intervals on vertical portions of the gas supply pipes 21 and 22 over a vertical length corresponding to a wafer support range of the wafer boat 5. The gas is discharged via each of the gas holes 21g and 22g in a horizontal direction. The gas supply pipe 23 is made of, for example, quartz, and is formed of a short quartz pipe provided to penetrate the sidewall of the manifold 3. The gas supply pipe 23 may also pass through the sidewall of the manifold 3 inward, be bent upward, and extend vertically, similar to the gas supply pipes 21 and 22.

The vertical portion (on which the gas holes 21g are formed) of the gas supply pipe 21 is provided inside the processing container 1 (e.g., the inner tube 1A). A metal-containing gas from a gas supply source 21a is supplied to the gas supply pipe 21 via a gas pipe. The metal-containing gas is, for example, TMA gas. The gas pipe is provided with a flow rate controller 21b and an on-off valve 21c. As a result, the metal-containing gas from the gas supply source 21a is supplied to the inside of the processing container 1 (e.g., the inner tube 1A) via the gas pipe and the gas supply pipe 21. The metal-containing gas contains the metal infiltrated into the resist film 140.

The vertical portion (on which the gas holes 22g are formed) of the gas supply pipe 22 is provided inside the processing container 1 (e.g., the inner tube 1A). A precursor gas from a gas supply source 22a is supplied to the gas supply pipe 22 via a gas pipe. The precursor gas is, for example, TPSOL gas. The gas pipe is provided with a flow rate controller 22b and an on-off valve 22c. As a result, the precursor gas from the gas supply source 22a is supplied to the inside of the processing container 1 (e.g., the inner tube 1A) via the gas pipe and the gas supply pipe 22. The precursor gas forms the protective film 150 containing silicon (Si) and oxygen (O) by using the metal infiltrated into the resist film 140 as a catalyst.

A purge gas from a gas supply source 23a is supplied to the gas supply pipe 23 via a gas pipe. The purge gas is, for example, nitrogen (N₂) gas but may be argon (Ar) gas. The gas pipe is provided with a flow rate controller 23b and an on-off valve 23c. As a result, the purge gas from the purge gas supply source is supplied to the inside of the processing container 1 (e.g., the inner tube 1A) via the gas pipe and the gas supply pipe 23.

The film forming apparatus 101 includes a gas discharger 45 that discharges a gas from the inside of the processing container 1. The gas discharger 45 includes an exhaust pipe 42 connected to an exhaust port 40 of the processing container 1. The exhaust port 40 is formed at the sidewall of the manifold 3 and communicates with an exhaust port 41 of the inner tube 1A via a passage between the outer tube 1B and the inner tube 1A. The exhaust port 41 of the inner tube 1A is formed to be elongated vertically corresponding to the wafer boat 5. The exhaust pipe 42 includes a pressure control valve 43 for controlling a pressure inside the processing container 1 and a vacuum pump 44.

The film forming apparatus 101 includes a heater 50. The heater 50 heats the processing container 1 and the substrate 100 therein. The heater 50 is provided in a cylindrical shape so as to surround an outer periphery of the processing container 1.

The film forming apparatus 101 includes a transferrer (not shown). The transferrer is a general transfer robot. The transferrer loads and unloads the substrate 100 into and from the processing container 1. The transferrer transfers the substrate 100 while the substrate 100 is placed on the wafer boat 5.

The film forming apparatus 101 includes a controller 60. The controller 60 is, for example, a computer, and includes a computation part such as a central processing unit (CPU) and a storage such as a memory. The storage stores programs that control various processes executed in the film forming apparatus 101. The controller 60 controls the operation of the film forming apparatus 101 by causing the computation part to execute the programs stored in the storage.

The film forming apparatus 101 may perform at least a part of the film forming method shown in FIG. 1, 7, or 9. The film forming apparatus 101 may perform all of steps S101 to S103 shown in FIG. 1. The film forming apparatus 101 may perform all of steps S301 to S306 shown in FIG. 7. If step S303 is performed using a spin coater or the like, steps S301, S302, and S304 to S306 except step S303 may be performed. The film forming apparatus 101 may perform steps S401 to S403, S405, and S406 except step S404 among steps S401 to S406 shown in FIG. 9. Herein, if the film forming apparatus 101 includes an apparatus configuration capable of performing both isotropic etching and anisotropic etching (e.g., a single-wafer type apparatus), the film forming apparatus 101 may perform all of steps S401 to S406.

Steps S102 and S103 in FIG. 1 may be performed inside the same processing container 1 or inside separate processing containers 1. Similarly, steps S302 to S306 in FIG. 7 may be performed inside the same processing container 1 or inside separate processing containers 1. Steps S402 to S406 in FIG. 9 may be performed inside the same processing container 1 or inside separate processing containers 1.

While the embodiments of the film forming method and film forming apparatus according to the present disclosure have been described, the present disclosure is not limited to the above-described embodiments. Various changes, modifications, substitutions, additions, deletions, and combinations are possible within the scope of the claims. These naturally fall within the technical scope of the present disclosure.

According to the present disclosure in some embodiments, it is possible to improve etching resistance of a resist film.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method, comprising:
preparing a substrate including a resist film with an opening formed on a top surface;
infiltrating a metal into at least an upper portion of the resist film by supplying a metal-containing gas containing the metal to the substrate; and
selectively forming a protective film containing silicon and oxygen on the top surface of the resist film compared to a side surface and a bottom surface of the opening by supplying a precursor gas containing silanol to the substrate.

2. The film forming method of claim 1, wherein the resist film includes an uppermost layer and one or more lower layers provided below the uppermost layer, and
wherein the metal is infiltrated into the uppermost layer more readily compared to all the lower layers.

3. The film forming method of claim 2, wherein the uppermost layer has a higher surface density of a functional group to which the metal is introduced compared to all the lower layers.

4. The film forming method of claim 1, comprising, in an order of:
infiltrating the metal into at least the upper portion of the resist film, forming a planarization film for planarizing a step difference of the resist film on the resist film, exposing the upper portion of the resist film by shaving the planarization film, forming the protective film on the upper portion of the resist film, and removing the planarization film that blocks the opening of the resist film.

5. The film forming method of claim 4, wherein the planarization film is an organic film.

6. The film forming method of claim 1, comprising, in an order of:
infiltrating the metal into at least the upper portion of the resist film, forming a conformal film along a step difference of the resist film on the top surface of the resist film and on the side surface of the opening of the resist film, exposing the upper portion of the resist film by selectively etching an upper portion of the conformal film, forming the protective film on the upper portion of the resist film, and removing the conformal film remaining on the side surface of the opening of the resist film.

7. The film forming method of claim 6, wherein the conformal film is an inorganic film.

8. The film forming method of claim 1, wherein the metal includes a metal or a semimetal having Lewis acid characteristics, or a compound of the metal or the semimetal.

9. The film forming method of claim 8, wherein the metal includes one or more elements selected from Al, Ti, Zr, Zn, Hf, B, and In.

10. A film forming apparatus comprising
a processing container;
a substrate holder configured to hold a substrate at an inside of the processing container;
a gas supplier configured to supply a gas to the inside of the processing container;
a gas discharger configured to discharge a gas from the inside of the processing container;
a transferrer configured to load and unload the substrate into and from the processing container; and
a controller configured to control the gas supplier, the gas discharger, and the transferrer to perform the film forming method of claim 1.
